(19) United States
(12) Patent Application Publication
(10) Pub. No.: US 2004/0000709 A1
(43) Pub. Date: Jan. 1, 2004

(54) Internal package interconnect with electrically parallel vias

(76) Inventor: Javier Delacruz, Summit, NJ (US)

Correspondence Address: SAMUEL BORODACH, Fish & Richardson P.C., Suite 2800, 45 Rockefeller Plaza, New York, NY, 10111, US

(21) Appl. No.: 10/183,274

(22) Filed: Jun. 26, 2002

(51) Int. Cl. H01L 21/44; H01L 21/50; H01L 23/495

(52) U.S. Cl. 257/700; 257/668; 257/701; 438/125; 257/703; 257/705

(57) ABSTRACT

An electronic package includes a multi-layer substrate module that includes electrically parallel vias to carry an electrical data signal between two nodes. For example, the vias may be coupled between nodes of different metallization layers in or on the substrate module. Alternatively, the vias may be coupled between a node of one of the metallization layers and a signal transmission line that feeds or receives data signals or an interconnection that connects the multi-layer module to a next higher level of the assembly, such as a printed circuit board. In other implementations, the vias may be coupled between a data signal transmission line and an interconnection to the next-higher level of the assembly.

### BACKGROUND

This disclosure relates to internal package interconnects with electrically parallel vias.

Microelectronics devices may contain many electronic components within an active semiconductor chip. To form a usable device, the semiconductor chip requires protection from the environment as well as electrical and mechanical connections to the surrounding components. The technology dealing with these requirements is called electronic packaging. The design of the chip provides access to terminals for input power and signal transmission and provides the electrical wiring for interconnections.

An electronic package may include a monolithic dielectric structure having a number of layers of insulating material which have conductor patterns, resistors and other electrical circuit elements on their surfaces. The layers may be thermally, mechanically or chemically fused together so that the circuit elements are buried within the structure. Vertical interconnects, also known as vias, may be formed through the insulating layers to provide interconnections between circuit elements in different layers.

### SUMMARY

An electronic package includes a multi-layer substrate module that includes multiple electrically parallel vias to carry an electrical data signal between two nodes. For example, the vias may be coupled between nodes of different metallization layers in or on the substrate module. Alternatively, the vias may be coupled between a node of one of the metallization layers and a signal transmission line that feeds or receives data signals or an interconnection that connects the multi-layer module to a next-higher level of the assembly, such as a printed circuit board. In other implementations, the vias may be coupled between a data signal transmission line and an interconnection to the next-higher level of the assembly.

The use of electrically parallel vias to carry the data signal(s) may help reduce the resistance and may reduce the effective layer-to-layer inductance. Such reductions may be particularly useful for carrying high frequency data signals through the multi-layer substrate module.

In various implementations, one or more of the following features may be present. The substrate module may include one or more capture pads which the vias intersect and may include a multi-layer ceramic substrate module. The vias may include a ceramic material, such as a low-temperature co-fired ceramic material. An electronic device may be mounted on and electrically coupled to the multi-layer substrate module.

A method also is disclosed in which an electrical data signal is passed from an electronic device to a multi-layer ceramic substrate module to which the device is mounted. The electrical data signal is carried simultaneously along electrically parallel vias in the multi-layer ceramic substrate module. The vias electrically couple a first node and a second node. The first node may be either on a data signal transmission line on the multi-layer substrate module or on a first electrically conductive layer in the multi-layer substrate module. The second node may be either on a second conductive layer in the multi-layer substrate module or an interconnection that electrically couples the multi-layer substrate module to a next-higher level assembly. The electrical data signal is passed from the multi-layer ceramic substrate module to a next-higher level assembly. In some implementations, the data signals may have a frequency greater than 9.9 Gigabits per second (Gbit/s).

Other features and advantages will be readily apparent from the following detailed description, the accompanying drawings and the claims.

### BRIEF DESCRIPTION OF THE DRAWINGS

FIG. 1 is a flow chart of a process for manufacturing a package for an electronic circuit.

FIG. 2 illustrates various steps in the manufacturing process.

FIG. 3 is a cross-section of an electronic package assembly.

FIG. 4 is a cross-section of the electronic package assembly showing additional details of a multi-layer ceramic substrate module according to one implementation.

FIG. 5 illustrates details of a turret via according to one implementation.

FIG. 6 is a cross-section of an electronic package assembly showing additional details of a multi-layer ceramic substrate module according to another implementation.

FIG. 7 is a partial cross-section of another example of an electronic assembly package that includes a turret via.

### DETAILED DESCRIPTION

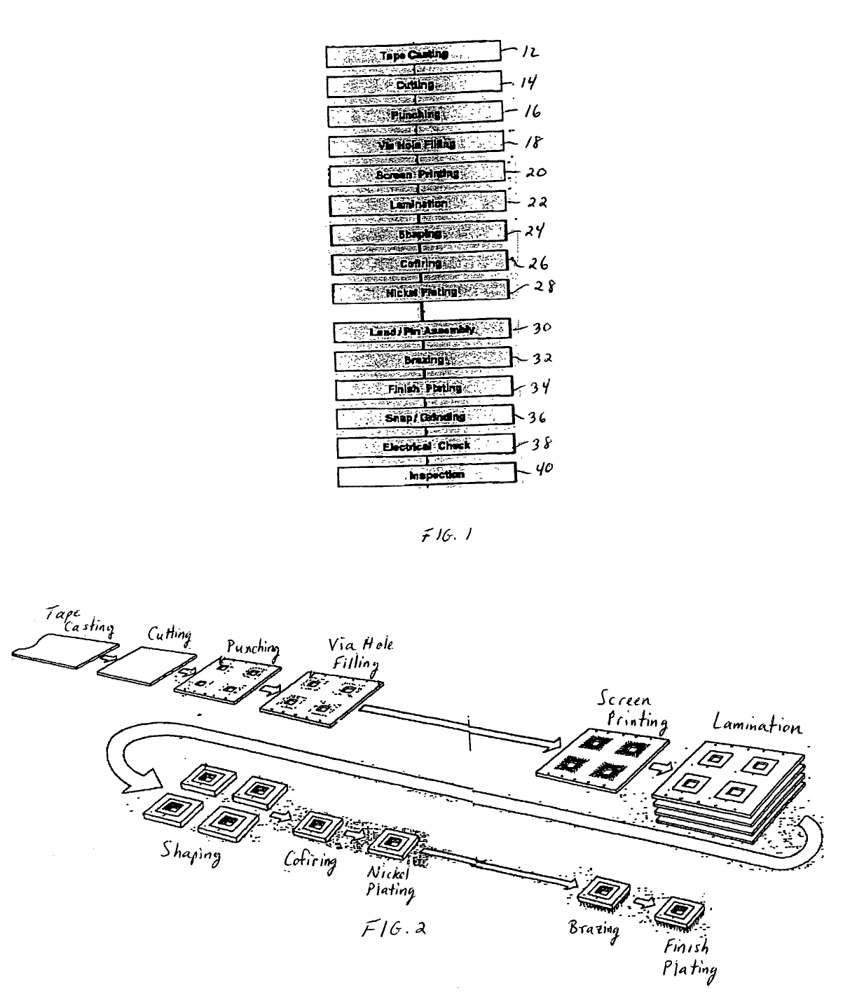

FIGS. 1 and 2 illustrate an example of an overall manufacturing process for making multi-layer electronic package assemblies. Other processes may include additional or different steps, or may differ in particular details.

Initially, unfired, flexible ceramic sheets may be tape cast 12 and cut 14. Via holes, cavities and other inside cutting may be punched 16 in the ceramic sheets layer-by-layer. The via holes may then be filled or coated 18 for electrical connection. Subsequent screen printing 20 may include the formation of conductor lines and various metallization pads. The ceramic sheets are then stacked according to the design sequence and bonded together during a lamination process 22.

Following lamination, a shaping process 24 may be used to cut the outside edge of the ceramic sheets to facilitate subsequent separation of the individual units from the master array. The ceramic and metallization layers then may be sintered simultaneously during a co-firing process 26 at a temperature, for example, in the range of about 1,500-1,600° F. To improve subsequent welding, pre-brazing nickel plating 28 may be performed. After assembly of the electrical leads and pins (block 30), metal parts such as lead frames, input/output (I/O) pins, seal rings and/or heat sinks may be bonded to metallized pads during a brazing process 32. During subsequent processing, exposed metal surfaces may be plated 34, for example, using gold with a nickel underplating.

The individual units then may be separated 36 from the master array. Final electrical testing 38 and quality assurance inspections 40 may be performed.

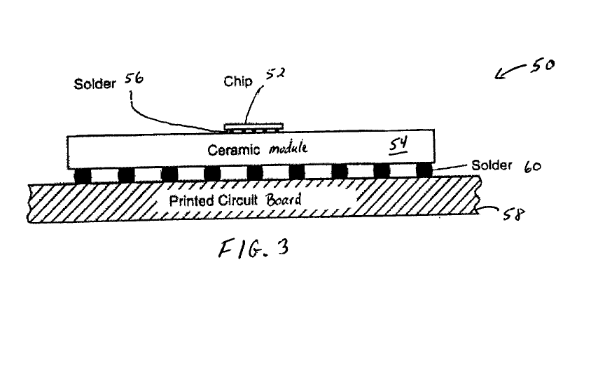

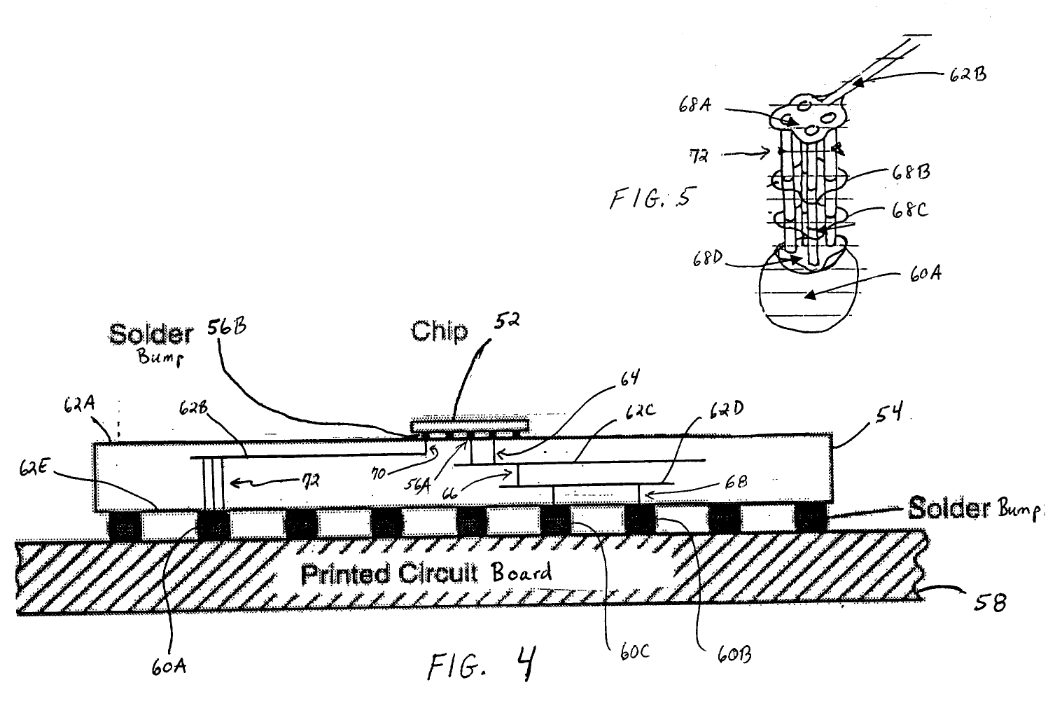

As shown in FIG. 3, the resulting electronic package assembly 50 may include a semiconductor flip-chip 52 or other electronic device mounted to the multi-layer ceramic substrate module 54, for example, through solder ball interconnections 56. The ceramic module 54 may be attached to the printed circuit board 58 through another set of solder ball interconnections 60.

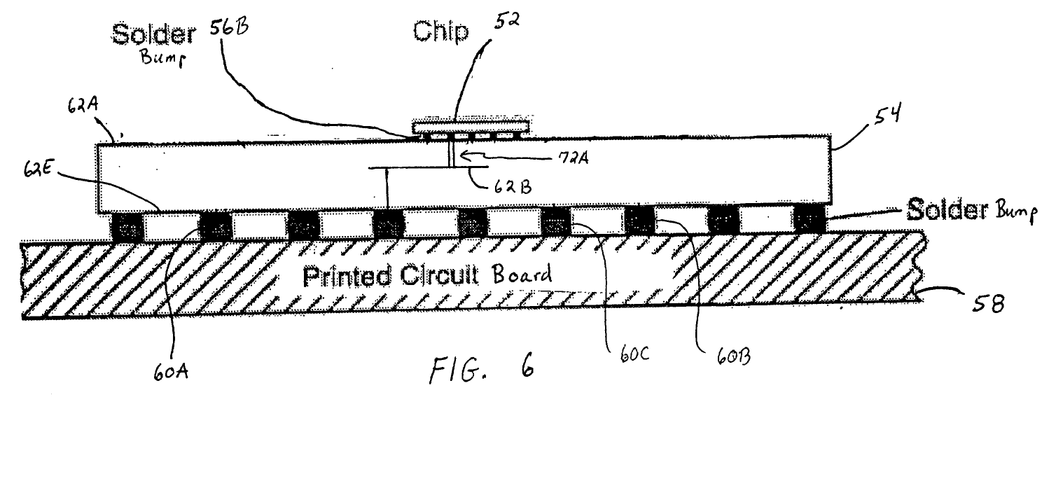

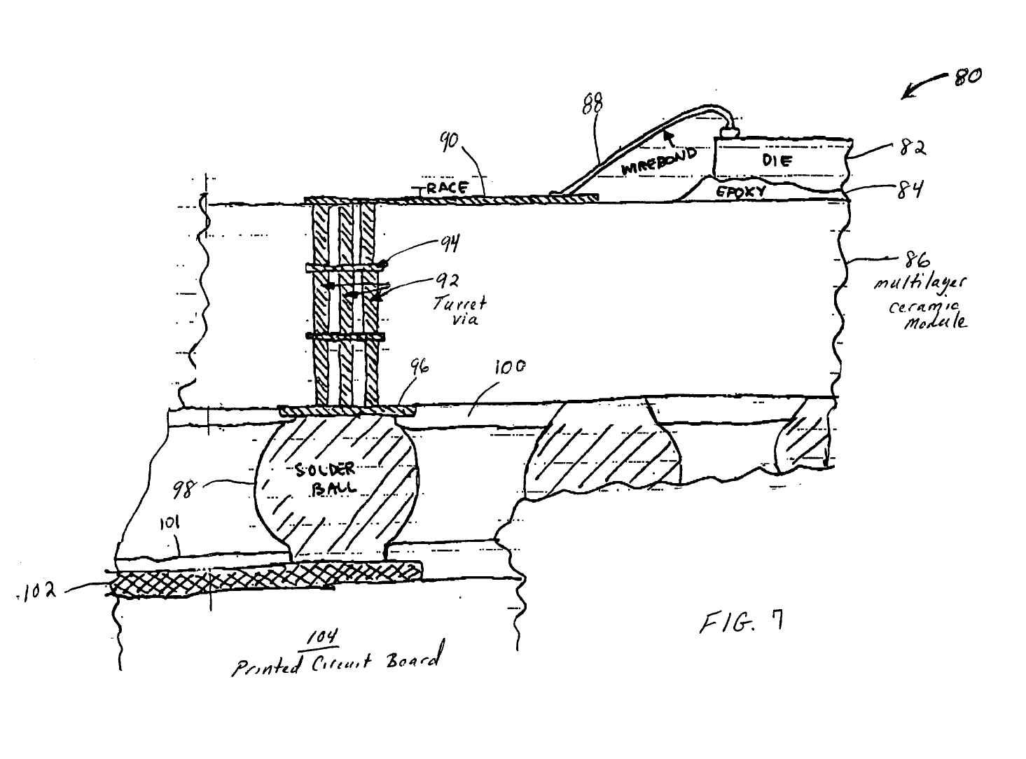

FIG. 4 illustrates further details of a multi-layer ceramic substrate module 54. As shown, the substrate module 54 includes five conductive or metallization layers 62A, 62B, 62C, 62D and 62E, separated by layers of ceramic material. The metallization layers and the package interconnects may be coupled by thermal vias or data signal vias.

For example, some of the interconnections, metallization lines and vias may help dissipate heat. Solder balls connecting the flip-chip 52 to the substrate module 54, such as the solder ball 56A, may be coupled, for example, to the metallization layers 62C, 62D through thermal vias 64, 66. Additional thermal vias 68 may carry the heat to the printed circuit board interconnections 60B, 60C.

Other interconnections, metallization lines and vias may carry data signals. As shown, for example, in FIG. 4, the solder bump 56B connects a signal input/output pin (not shown) on the flip-chip 52 to the substrate module 54. The solder bump 56B may be coupled through a via 70 to the metallization layer 62B. The metallization layer 62B is coupled by a turret via 72 to the interconnect solder bump 60A. The turret via 72 includes multiple parallel vias that connect the metallization layer 62B to the interconnect solder bump 60A. Each of the vias in the turret via 72 contacts both the metallization layer 62B and the solder bump 60A.

Various materials, including low temperature co-fired ceramic materials, may be used for the electrically parallel vias. Other materials also may be used.

As shown in FIG. 5, capture pads 68A, 68B, 68C and 68D may be provided at one or more of the layers to help compensate for layer-to-layer misalignment. The capture pads may comprise the same material as the vias 72.

Electrically parallel vias, such as those shown in FIG. 5, may be used to carry data signals, for example, between nodes of two different metallization layers, between a node of one of the metallization layers and a signal transmission line that feeds or receives data signals, or between a node of one of the metallization layers and an interconnection that connects the multi-layer module to the next-higher level of the assembly (in this case, the printed circuit board 58). Each of the vias contacts both nodes. Using electrically parallel vias to carry data signals may help reduce the resistance and may reduce the effective layer-to-layer inductance of the signal. Reductions in resistance can be particularly important for data signals at high frequencies, such as signals with a frequency greater than 9.9 Gbits/s. The techniques may be particularly advantageous for data signals with frequencies in the range of about 9.9 to 80 Gigabits per second (Gbit/s). The techniques may, however, be used with data signals having higher or lower frequencies as well.

Although a solder ball 60A is shown in FIGS. 4 and 5 as the interconnection from the multi-layer ceramic module 54 to the next-higher level assembly (in this case, the printed circuit board 58), other types of package interconnections may be used instead, including land grid pads, brazen leads, coaxial launches, pins and/or columns. Similarly, instead of the flip-chip solder bump 56B, other types of connections may be provided between the semiconductor chip 52 and the multi-layer module 54. Such connections include, for example, wire bonds and ribbons.

FIG. 6 illustrates an electronic package assembly in which a turret via 72A provides the electrical data signal path from an interconnection to the chip 52 to a metallization or other conductive layer 62B in the multi-layer ceramic substrate module 54. The turret via 72A includes electrically parallel vias to carry a data signal from the chip interconnection to the metallization layer 62B.

FIG. 7 illustrates an example of a wire-bonded electronic package assembly 80 that includes a turret via 92. A semiconductor die 82 may be attached to a multi-layer ceramic module 86, for example, through use of an epoxy 84. Input/output connections to the die may be coupled electrically to a metal trace 90 on the surface of the ceramic module through a wire bond 88. The trace may be coupled electrically through a turret via 92 to a solder ball 98 that provides the interconnection from the multi-layer ceramic module to the next-higher level assembly (in this case, the printed circuit board 104). In this example, data signals may be carried from the die 82 through the multi-layer ceramic module 86 to the printed circuit board 104 by way of the turret via 92. The turret via 92 includes electrically parallel vias and may include one or more capture pads 94 to help compensate for layer-to-layer misalignment. The solder ball interconnection 98 may be sandwiched between metallization layers 96, 102, with the lower metallization layer providing the electrical connection to the printed circuit board 104. Optional solder masks 100, 101 may be present as well.

As discussed above, using parallel vias to carry data signals may help reduce the resistance and may reduce the effective layer-to-layer inductance of the signal. Use of the turret via may be particularly advantageous for data signals at high frequencies.

Other implementations are within the scope of the claims.

What is claimed is:

1. An electronic package comprising:
a multi-layer substrate module comprising electrically parallel vias to carry an electrical data signal between a node of a first layer of the multi-layer substrate module and a node of a second layer of the multi-layer substrate module, each of the vias contacting each of the nodes; and
an electronic device mounted on and electrically coupled to the multi-layer substrate module.

2. The electronic package of claim 1 wherein the substrate module comprises a capture pad which the vias intersect.

3. The electronic package of claim 1 wherein the substrate module comprises a plurality of capture pads which the vias intersect.

4. The electronic package of claim 1 wherein the substrate module comprises a multi-layer ceramic module.

5. The electronic package of claim 1 wherein the vias comprise a ceramic material.

6. The electronic package of claim 1 wherein the vias comprise a low-temperature co-fired ceramic material.

7. The electronic package of claim 1 wherein the nodes are on metallization layers of the multi-layer substrate module.

8. The electronic package of claim 1 wherein the electronic device comprises a semiconductor chip.

9. The electronic package of claim 8 wherein the semiconductor chip is wire bonded to the multi-layer substrate module.

10. The electronic package of claim 9 wherein the semiconductor chip comprises a flip-chip.

11. The electronic package of claim 1 comprising:
a printed circuit board,
wherein the multi-layer substrate module is mounted on and electrically coupled to the printed circuit board.

12. The electronic package of claim 1 wherein the electronic device includes an input/output data signal lead electrically coupled to the vias.

13. An electronic package comprising:
a printed circuit board;
a multi-layer substrate module mounted on the printed circuit board, the multilayer substrate module comprising an electrically conductive layer;
an interconnection electrically coupling the multi-layer substrate module to the printed circuit board; and
an electronic device mounted on the multi-layer substrate module and electrically coupled to the multi-layer substrate module,
the multi-layer substrate module comprising electrically parallel vias to carry an electrical data signal between a node of the electrically conductive layer and the interconnection, each of the vias contacting the node of the conductive layer and the interconnection.

14. An electronic package comprising:
a printed circuit board;
a multi-layer substrate module mounted on and electrically coupled to the printed circuit board;
a data signal transmission line on the multi-layer substrate module; and
an electronic device mounted on the multi-layer substrate module and electrically coupled to the data transmission line;
an interconnection electrically coupling the multi-layer substrate module to the printed circuit board;
the multi-layer substrate module comprising electrically parallel vias to carry an electrical data signal between the data signal transmission line and the interconnection, each of the vias contacting the data signal transmission lines and the interconnection.

15. An electronic package comprising:
a multi-layer substrate module comprising an electrically conductive layer;
a data signal transmission line on the multi-layer substrate module and electrically coupled to the metallization layer; and
an electronic device mounted on the multi-layer substrate module and electrically coupled to the data transmission line,
the multi-layer substrate module comprising electrically parallel vias to carry an electrical data signal between the data signal transmission line and a node of the electrically conductive layer, each of the vias contacting the data signal transmission line and the node of the conductive layer.

16. The electronic package of any one of claims 13, 14 or 15 wherein the vias comprise a ceramic material.

17. The electronic package of any one of claims 13, 14 or 15 wherein the vias comprise a low temperature co-fired ceramic material.

18. The electronic package of any one of claims 13, 14 or 15 wherein the multi-layer substrate module comprises a multi-layer ceramic substrate module.

19. An electronic package comprising:
a multi-layer ceramic substrate module comprising a plurality of metallization layers and a plurality of electrically parallel vias to carry an electrical data signal between a node of a first one of the layers and a node of a second one of the layers.

20. The electronic package of claim 19 wherein the vias comprise a low temperature co-fired ceramic material.

21. The electronic package of claim 20 comprising a capture pad which the vias intersect.

22. A method comprising:
causing an electrical data signal to be passed from an electronic device to a multilayer ceramic substrate module to which the device is mounted;
carrying the electrical data signal simultaneously along electrically parallel vias in the multi-layer ceramic substrate module, the vias electrically coupling a first node and a second node, wherein the first node is either on a data signal transmission line on the multi-layer substrate module or on a first electrically conductive layer in the multi-layer substrate module, and wherein the second node is either on a second conductive layer in the multi-layer substrate module or an interconnection that electrically couples the multilayer substrate module to a next-higher level assembly; and
passing the electrical data signal from the multi-layer ceramic substrate module to a next-higher level assembly.

23. The method of claim 22 wherein the electrical data signal has a frequency greater than 9.9 Gigabits per second.

24. The method of claim 22 comprising passing the electrical data signal from the multi-layer ceramic substrate module to a printed circuit board.
